(19) United States
(12) Patent Application Publication
(10) Pub. No.: US 2016/0254244 A1
(43) Pub. Date: Sep. 1, 2016

(54) Systems and Methods Utilizing Anisotropic Conductive Adhesives

(71) Applicant: SunRay Scientific, LLC, Long Branch, NJ (US)

(72) Inventor: S. Kumar Khanna, Carmel, IN (US)

(21) Appl. No.: 15/152,530

(22) Filed: May 11, 2016

Related U.S. Application Data
(63) Continuation-in-part of application No. 14/054,529, filed on Oct. 15, 2013, now Pat. No. 9,365,749.
Application No. 14/054,529 is a continuation-in-part of application No. 14/512,535, filed on Oct. 13, 2014.
(60) Provisional application No. 61/829,365, filed on May 31, 2013.
(60) Provisional application No. 61/894,469, filed on Oct. 23, 2013.
(60) Provisional application No. 62/160,582, filed on May 12, 2015.

(51) Int. Cl. H01L 23/00; H05K 1/18; H05K 1/02; H01L 23/66; H05K 1/09; H01L 33/62; H01L 25/065; H01L 25/075; H05K 1/11; H05K 1/03

(52) U.S. Cl. CPC H01L 24/32; H05K 1/11; H05K 1/181; H05K 1/028; H05K 1/0274; H05K 1/0306; H05K 1/0353; H05K 1/09; H01L 33/62; H01L 25/0655; H01L 25/0753; H01L 23/66; H05K 2201/10106; H05K 2201/10098; H01L 2924/15738; H01L 2924/15724; H01L 2924/01047; H01L 2924/12041; H01L 2924/1421; H01L 2224/32225; H01L 2224/2929; H01L 2924/0675; H01L 2924/068; H01L 2223/6677; H01L 2924/0665; H01L 2224/29355; H01L 2224/29439; H01L 2924/01013

(57) ABSTRACT

Illustrative embodiments of systems and method utilizing anisotropic conductive adhesive(s) (“ACA”) are disclosed. In at least one illustrative embodiment, a substrate may comprise one or more electrical contacts, and one or more integrated circuits may be secured to the substrate by ACA. The ACA may comprise a plurality of particles suspended in a binder, where the plurality of particles form electrically conductive and isolated parallel paths between the one or more electrical contacts and the one or more integrated circuits as a result of the ACA being subjected to a magnetic field before or during curing of the binder.

### CROSS-REFERENCE TO RELATED APPLICATIONS

This application is a continuation-in-part of U.S. patent application Ser. No. 14/054,529, filed Oct. 15, 2013, and a continuation-in-part of U.S. patent application Ser. No. 14/512,535, filed Oct. 13, 2014, and claims the benefit of U.S. Provisional Patent Application No. 61/829,365, filed May 31, 2013, of U.S. Provisional Patent Application No. 61/894,469, filed Oct. 23, 2013, and of U.S. Provisional Patent Application No. 62/160,582, filed May 12, 2015.

### BACKGROUND

Anisotropic conductive adhesive(s) (“ACA”) may be utilized to form conductive paths between pairs of aligned electrical contacts, such as between a contact of an integrated circuit and a contact of a substrate (e.g., a printed circuit board). A typical ACA includes conductive particles suspended in a binder. Such ACA may be interposed in an uncured state between the integrated circuit or integrated circuit package and the substrate, after which the ACA may be cured in the presence of a magnetic field. The conductive particles of the ACA will form conductive paths between contacts of the integrated circuit or integrated circuit package and of the substrate while, at the same time, the ACA bonds the integrated circuit or integrated circuit package to the substrate.

### SUMMARY

According to one aspect, a substrate may comprise one or more electrical contacts, and one or more integrated circuits may be secured to the substrate by ACA. The ACA may comprise a plurality of particles suspended in a binder, where the plurality of particles form electrically conductive and isolated parallel paths between the one or more electrical contacts and the one or more integrated circuits as a result of the ACA being subjected to a magnetic field before or during curing of the binder.

In some embodiments, the one or more integrated circuits may comprise one or more light-emitting diodes.

In some embodiments, the one or more integrated circuits may comprise one or more chip-on-board light-emitting diodes.

In some embodiments, the one or more integrated circuits may comprise one or more radio-frequency identification chips.

In some embodiments, the one or more integrated circuits may comprise one or more packaged integrated circuits.

In some embodiments, the one or more integrated circuits may comprise one or more unpackaged integrated circuits.

In some embodiments, the substrate may comprise a rigid substrate.

In some embodiments, the substrate may comprise a flexible substrate.

In some embodiments, the substrate may comprise a transparent substrate.

In some embodiments, the substrate may comprise an opaque substrate.

In some embodiments, the substrate may comprise plastic.

In some embodiments, the substrate may comprise glass.

In some embodiments, the substrate may comprise a paper.

In some embodiments, the substrate may comprise polyester.

In some embodiments, the substrate may comprise polyvinyl chloride.

In some embodiments, the substrate may comprise polycarbonate.

In some embodiments, the substrate may comprise polystyrene.

In some embodiments, the one or more electrical contacts may comprise silver.

In some embodiments, the one or more electrical contacts may comprise aluminum.

In some embodiments, the one or more electrical contacts may be transparent.

In some embodiments, the substrate may further comprise an antenna connected to at least one of the electrical contacts.

In some embodiments, the ACA may be cured by applying heat to the binder of the ACA.

In some embodiments, the ACA may be cured by applying ultraviolet light to the binder of the ACA.

In some embodiments, the ACA may be cured by applying electromagnetic radiation to the binder of the ACA.

### BRIEF DESCRIPTION OF THE DRAWINGS

The concepts described in the present disclosure are illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. The detailed description particularly refers to the accompanying figures in which:

FIG. 1 is a perspective view of one illustrative embodiment of the positioning of an integrated circuit package on an ACA deposited on a substrate;

FIG. 2A is a cross-sectional view of the integrated circuit package in spaced relation to the substrate and the ACA taken along section lines 2A-2A in FIG. 1;

FIG. 2B is a cross-sectional view of the integrated circuit package in contact with the ACA deposited on the substrate, from the same perspective as FIG. 2A;

FIG. 3 is a schematic representation of one illustrative embodiment of a curing system having a magnetic field generator;

FIG. 4 includes a plot of current versus time that may be used to drive the magnetic field generator of FIG. 3, as well as field strength versus time for the resulting magnetic field;

FIG. 5 is an isolated diagrammatic cross-section of one illustrative embodiment of a pair of isolated, parallel conductive paths in a cured ACA;

FIG. 6 is a plot of insulation resistance versus time for one illustrative embodiment of an ACA, showing effects of the migration of the electrically conductive material of particles of the ACA;

FIG. 7A is an isolated diagrammatic cross-section of one illustrative embodiment of an uncured ACA, showing a random distribution of particles in the binder prior to being subjected to a magnetic field;

FIG. 7B is an isolated diagrammatic cross-section of the ACA of FIG. 6A, showing an ordered distribution of particles in the binder after being subjected to the magnetic field; and

FIG. 8 is a plot of insulation resistance versus time for another illustrative embodiment of an ACA, showing reduced migration of the electrically conductive material of particles of the ACA (as compared to the ACA of FIG. 6).

### DETAILED DESCRIPTION OF THE DRAWINGS

While the concepts of the present disclosure are susceptible to various modifications and alternative forms, specific exemplary embodiments thereof have been shown by way of example in the drawings and will herein be described in detail. It should be understood, however, that there is no intent to limit the concepts of the present disclosure to the particular forms disclosed, but on the contrary, the intention is to cover all modifications, equivalents, and alternatives falling within the spirit and scope of the present disclosure.

It should also be understood that any numerical range recited herein is intended to include all sub-ranges subsumed therein. For example, a range of “1 to 10” is intended to include all sub-ranges between and including the recited minimum value of 1 and the recited maximum value of 10, i.e., having a minimum value equal to or greater than 1 and a maximum value of equal to or less than 10. Because the disclosed numerical ranges are continuous, they include every value between the minimum and maximum values. Unless expressly indicated otherwise, the various numerical ranges specified in this application are approximations.

As used in the present disclosure, the term “polymer” encompasses oligomers and includes, without limitation, both homopolymers and copolymers. As used herein, “(meth)acrylate” and like terms are intended to include both acrylates and methacrylates. As used herein, the term “aryl” refers to aromatic groups that include, without limitation, phenyl, biphenyl, benzyl, xylyl, napthalenyl, anthracenyl, and the like, as well as heterocyclic aromatic groups that include, without limitation, pyridinyl, pyrrolyl, furanyl, thiophenyl, and the like.

The present disclosure relates to various systems and methods utilizing anisotropic conductive adhesive(s) (“ACA”). The presently disclosed ACA have been found to be particularly suitable for use in forming conductive paths between conductive contacts of an integrated circuit (either packaged or unpackaged) and conductive contacts on a substrate that are aligned with the conductive contacts on the integrated circuit, while avoiding electrical shorting between adjacent conductive paths. The disclosed ACA are particularly suitable for creating isolated, parallel conductive paths between contacts of an integrated circuit and contacts of a substrate having an edge-to-edge spacing less than 250 including spacing as small as about 20 μm to 25 μm.

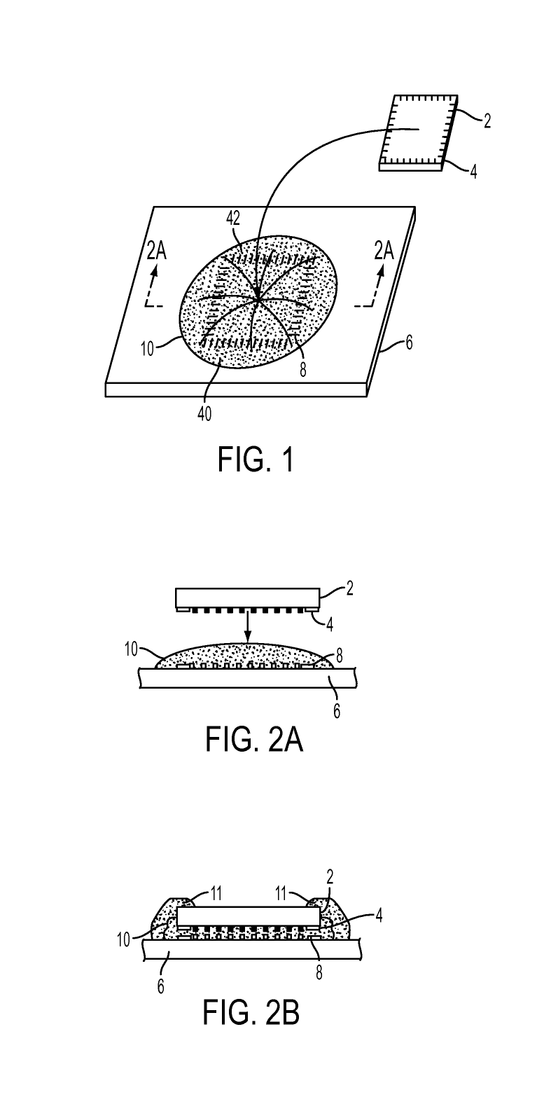

With reference to FIG. 1, an integrated circuit package 2 includes a plurality of closely spaced contacts 4, typically positioned on or adjacent the edges of package 2. In FIG. 1, package 2 is illustrated as a leadless chip carrier package. However, in other embodiments, the presently disclosed ACA may be used with other surface mount integrated circuit packages, such as ball grid arrays, dual inline or quad packages having gull-wing or j-shaped leads, and quad flat packs having laterally extending leads, or any other form of integrated circuit package having closely spaced leads. In addition, it is also contemplated that the presently disclosed ACA may be used with unpackaged integrated circuits.

As shown in FIG. 1, package 2 is received on a substrate 6 having a plurality of closely spaced contacts 8 disposed in mirror image relation to the contacts 4 of package 2. The substrate 6 may be formed of any number of materials, including, but not limited to, plastic, paper, and glass. For instance, in some illustrative embodiments, the substrate 6 may be formed of polyester, polyvinyl chloride (“PVC”), polycarbonate, or polystyrene. In some embodiments, the substrate 6 may be formed as a rigid board. In other embodiments, the substrate 6 may be formed as a flexible sheet or film. In still other embodiments, the substrate 6 may be partially rigid and partially flexible. It is contemplated that, in various embodiments, the substrate 6 may be transparent, opaque, or partially transparent and partially opaque.

The contacts 8, as well as other electrical traces (not shown), may be formed of one or more metals and metal alloys, such as silver and aluminum, by way of example. In other embodiments, the contracts 8 and traces may be formed of other conductive materials, such as transparent conductive inks, by way of example. The contacts 8 and traces may be printed on, or otherwise deposited on, the substrate 6 using any suitable method(s). Prior to mounting package 2 on substrate 6, a drop or coating of uncured ACA 10 is deposited on substrate 6 over the plurality of contacts 8.

Referring now to FIGS. 2A and 2B, package 2 is positioned with its contacts 4 in opposition to the contacts 8 of substrate 6. More specifically, each contact 4 of package 2 is positioned in alignment with a corresponding contact 8 of substrate 6. Thereafter, as shown in FIG. 2B, package 2 is moved into contact with ACA 10. In response to this contact, ACA 10 displaces somewhat. However, the viscosity of ACA 10 may be such that contacts 4 of package 2 and contacts 8 of substrate 6 are maintained in spaced relation by ACA 10. In other words, package 2 is moved into contact with ACA 10 such that contacts 4 of package 2 and contacts 8 of substrate 6 are not in physical contact with each other. Furthermore, in the illustrated embodiment, the displacement of ACA 10 is due primarily to the weight of package 2, and only slightly due to the force utilized to move package 2 into contact with ACA 10.

After package 2 is deposited on ACA 10 with each contact 4 in alignment with a corresponding contact 8 of substrate 6, an adhesive 11 may be used to temporarily secure the relative position of package 2 and substrate 6. For instance, adhesive 11 may be deposited around the perimeter of package 2. In other embodiments, adhesive 11 may be deposited on only two or more corners of package 2. After the ACA 10 has been cured, as described below, the adhesive 11 may be removed. It will be appreciated that the use of adhesive 11 to secure the relative position of package 2 and substrate 6 prior to curing of ACA 10 is optional and may not be desirable or needed in some embodiments.

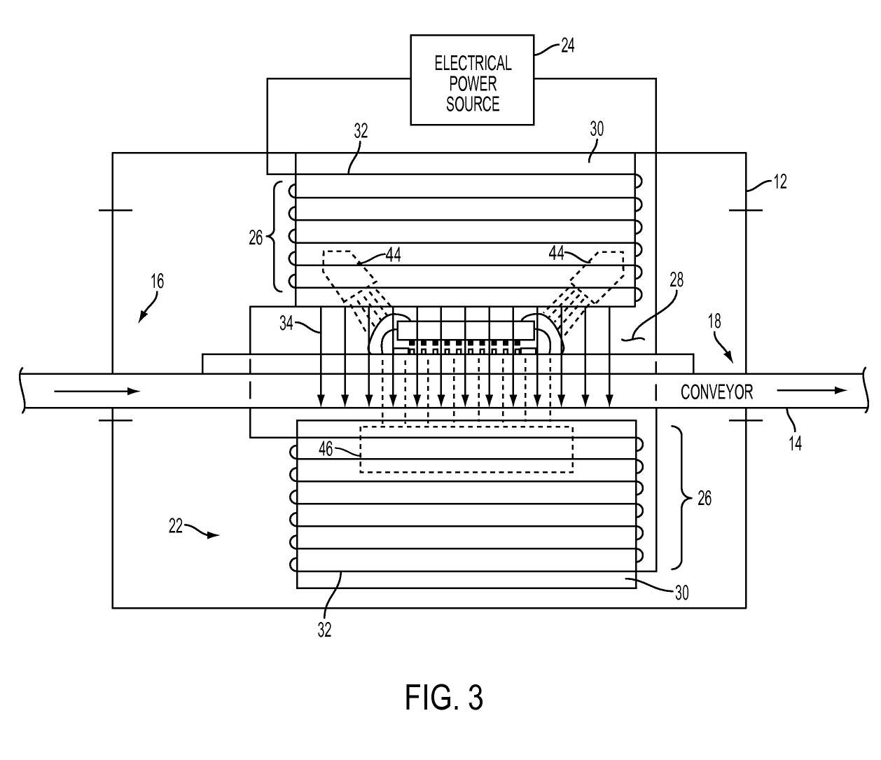

As will be described further below, ACA 10 may be cured using heat and/or electromagnetic radiation, such as ultraviolet (“UV”) light. With reference to FIG. 3, the entire assembly (i.e., package 2, substrate 6, and ACA 10) is positioned in a curing system 12. In a production environment, curing system 12 can have a conveyor 14 which extends through curing system 12 between an inlet 16 and an outlet 18 thereof for transporting the assembly. Curing system 12 may be embodied as an enclosure of any suitable shape and size in which the assembly can be positioned. In some illustrative embodiments, curing system 12 may be embodied as a curing oven 12 that includes a heater 20 for heating the atmosphere (e.g., air) inside of the curing oven 12. In other illustrative embodiments, the curing system 12 may additionally or alternatively include one or more light sources 44, 46 for curing the ACA 10.

Curing system 12 includes a magnetic field generator 22 disposed therein which is coupled to and controlled by an electrical power source 24 disposed external to curing system 12. Magnetic field generator 22 includes a pair of poles 26 disposed in spaced relation across a gap 28 in which package 2 received on ACA 10 deposited on substrate 6 is positioned in or passes through on conveyor 14. Each pole 26 includes a pole element 30 of ferromagnetic or paramagnetic material having one or more windings 32 of wire (or other suitable conductive material). Windings 32 are electrically insulated from pole elements 30 by a suitable insulator on pole elements 30 and/or a suitable insulator around the wire forming windings 32. Windings 32 of each pole 26 are connected to each other and to electrical power source 24 such that, in response to electrical power source 24 supplying windings 32 with a suitable electrical current, a magnetic field 34 is generated across gap 28.

In the illustrative embodiment of FIG. 3, poles 26 are configured so that magnetic field 34 is highly homogeneous, at least where package 2 received on ACA 10 deposited on substrate 6 is positioned in curing system 12 during curing of ACA 10. In the illustrative embodiment, magnetic field 34 has a homogeneity of greater than 98.5%. In other embodiments, magnetic field 34 may have other levels of homogeneity (e.g., 95%).

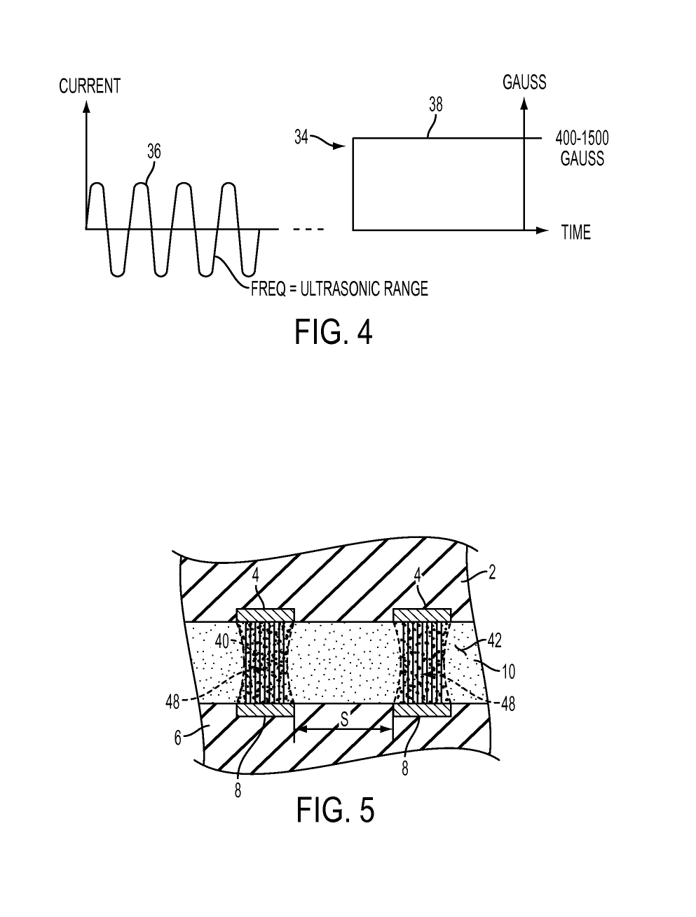

Referring now to FIG. 4, electrical power source 24 may initially apply an alternating current signal 36 to windings 32 for a time period (e.g., between 15 and 30 seconds), followed by a direct current signal 38 for the remainder of the curing time of ACA 10. The amplitude of alternating current signal 36 may be selected based on the sizes of particles (discussed below) included in ACA 10. By way of example, the amplitude of alternating current signal 36 may be selected so that magnetic field 34 has an alternating magnetic field strength between 10 and 100 gauss. The value of direct current signal 38 may be selected so that magnetic field 34 has a static magnetic field strength between 200 and 2,000 gauss.

Magnetic field 34 shown in FIG. 3 includes the alternating magnetic field produced by magnetic field generator 22 in response to alternating current signal 36 and the static magnetic field produced by magnetic field generator 22 in response to direct current signal 38. It has been observed that alternating current signal 36 operating in the ultrasonic frequency range (e.g., between about 20 kHz and about 500 kHz) works well with ACA 10. However, in other embodiments, other frequencies outside of the ultrasonic frequency range can also be utilized.

In embodiments utilizing a heat-curable ACA 10, curing oven 12 is heated, or preheated, to a suitable curing temperature for the heat-cured ACA 10. In the illustrative embodiment, ACA 10 is subjected to this curing temperature for a suitable curing interval while being subjected to magnetic field 34. In other embodiments, ACA 10 may be cured within a short time (e.g., one minute or less) after being subjected to magnetic field. In some embodiments, the curing temperature and the curing interval of ACA 10 may vary between 70° C. for about 30 minutes to 150° C. for about 5-7 minutes.

In embodiments utilizing a UV-curable ACA 10, the curing system 12 includes a number of light sources 44, 46 positioned therein (e.g., within windings 32). For instance, a number of light sources 44 may illuminate ACA 10 from one or more sides of the assembly. In such embodiments, any adhesive 11 used to secure the relative position of package 2 and substrate 6 may be at least partially transparent to allow the UV light generated by light sources 44 to reach ACA 10. Additionally or alternatively, a light sources 46 may illuminate ACA 10 from the bottom of the assembly. In such embodiments, substrate 6 and conveyor 14 may be at least partially transparent to allow the UV light generated by light source 46 to reach ACA 10.

In the illustrative embodiment, ACA 10 is subjected to UV light for a suitable curing interval while being subjected to magnetic field 34. In other embodiments, ACA 10 may be cured within a short time (e.g., one minute or less) after being subjected to magnetic field. In such embodiments, one or more of light sources 44, 46 may be positioned outside of windings 32 (e.g., nearer the outlet 18 of the curing system 12). As such, the conveyor 14 may first move the assembly into magnetic field 34 and then move the assembly into the UV light generated by light sources 44, 46.

With reference to FIG. 5, once cured to a solid, ACA 10 forms conductive paths between each contact 4 of package 2 and each corresponding contact 8 of substrate 6 in alignment therewith. It has been observed that the presently disclosed ACA 10 can form electrically conductive, but isolated, parallel conductive paths 48 between adjacent pairs of aligned contacts having an edge-to-edge spacing (“S”) as small as 20-25 μm.

As shown in FIGS. 1 and 5, ACA 10 includes a plurality of particles 40 suspended in a binder 42 that is curable using heat and/or UV light. Each of particles 40 may include a ferromagnetic material (e.g., nickel, iron, cobalt, or the like) coated with a layer of electrically conductive material, such as a noble metal (e.g., gold, silver, or the like). By way of example, particles 40 may include one or more of the following: solid nickel coated spheres, solid nickel flakes, solid carbon/graphite spheres, solid glass spheres, solid mica particles or flakes, and hollow glass spheres. As used herein, the terms “sphere” or “spheres” generally refers to particles are ball-shaped, egg-shaped or minor variations of ball-shaped and egg-shaped. Particles 40 that include a solid carbon/graphite sphere, a solid glass sphere, a solid mica particle or flake, or a hollow glass sphere may each include a coating of ferromagnetic material (e.g., nickel) between the outside surface of the sphere and the coating of electrically conductive material. The coating of ferromagnetic material on these otherwise non-magnetic materials renders them susceptible to the influence of magnetic field 34.

In the illustrative embodiment, each particle 40 along with the one or more coatings thereon has a maximum dimension less than 100 μm. In some embodiments, each particle 40 along with the one or more coatings thereon may have a maximum dimension less than 25 μm. In still embodiments, each particle 40 along with the one or more coatings thereon may have a maximum dimension less than 1 μm. As used herein, the term “maximum dimension” means the largest dimension of the particle measured in any direction. For example, if a particle 40 is a sphere, the maximum dimension is the outside diameter of the electrically conductive material deposited on the sphere. If the particle 40 is a flake having an irregular shape, the maximum dimension is the dimension between the two points of the electrically conductive material deposited over the particle 40 that are farthest apart.

It has been observed that particles 40 having an average maximum dimension between 1 μm and 25 μm enable the formation of isolated, parallel conductive paths between adjacent pairs of aligned contacts having an edge-to-edge spacing as close as 20-25 μm. It will be appreciated a plurality of particles having this average maximum dimension will have some particles having less than 1 μm (e.g., submicron) and some particles having a maximum dimension greater than 25 To this end, it has been observed that in a population of particles 40 with an average maximum dimension between 1 μm and 25 μm, some of the particles can have a maximum dimension in the submicron range.

One illustrative embodiment of ACA 10 includes a binder 42 formed from the reaction product of between 82% and 91% by weight of a compound and no more than about 6% by weight of a catalyst. The compound includes about one-third by weight of each of an aromatic epoxy resin, a dimer fatty acid diglycidyl ester, and an oxirane. Any suitable aromatic epoxy resin may be used in the compound. Suitable aromatic epoxy resins include, but are not limited to, diglycidyl ethers of bisphenol-A and bisphenol-F and other such resins, such as those available from EPON Resins from Resolution Performance Products, Houston, Tex. Any suitable dimer fatty acid diglycidyl ester may be used in the compound. Suitable dimer fatty acid diglycidyl esters include, but are not limited to, those of the formula:

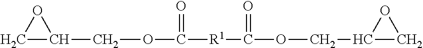

where R¹ is C₁-C₂₀ alkylene, arylene, or alkarylene. Any suitable oxirane may be used in the compound. Suitable oxiranes include, but are not limited to, those of the formula:

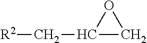

where R² is linear or branched C₁-C₂₀, alkyl, aryl, alkaryl, or is derived from a poly ether of the formula:

—OR³—OₙR⁴

where R³ is a linear or branched C₁-C₁₂ alkylene and R⁴ is a linear or branched C₁-C₂₀ alkyl, aryl or alkaryl group, and “n” is an integer from 1 to 100. In some embodiments, the oxirane may be (butoxy methyl)-butyl glycidyl ether. The aromatic epoxy resin may be the reaction product of about one-half by weight of each of bisphenol-A and epichlorohydrin. The catalyst may include a quaternary cyanyl R-substituted amine. The R group in the quaternary cyanyl R-substituted amine may be a C₁-C₂₀ linear or branched alkyl, aryl, or aralkyl group. In this illustrative embodiment, particles 40 (including solid nickel spheres coated with silver and/or solid nickel flakes coated with silver) may comprise between 5% and 14% of ACA 10 by weight.

Another illustrative embodiment of ACA 10 includes the same particles 40 and a similar binder 42 to the illustrative embodiment of ACA 10 just described, except that binder 42 includes about 10% by weight of a UV curable modifier which replaces a corresponding weight percentage of the compound. More specifically, binder 42 in this illustrative embodiment of ACA 10 is formed from the reaction product of the UV curable modifier, the catalyst, and the above described compound. One exemplary UV curable modifier is formed from the reaction product of between 8% and 12% by weight of a (meth)acrylate ester, between 76% and 84% by weight of (meth)acrylated urethane, and between 4% and 5% by weight of a hydroxy alkyl aryl ketone. Any suitable (meth)acrylate ester may be used in the UV curable modifier. Suitable (meth)acrylate esters include, but are not limited to, those of the formula of:

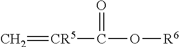

where R⁵ is H or methyl and R⁶ is a linear, branched, or cyclic C₁-C₂₀ alkyl, aryl, alkaryl, or aralkyl group. In one embodiment, the (meth)acrylate ester is isobutyl (meth)acrylate. Any suitable hydroxy alkyl aryl ketone may be used in the UV curable modifier. Suitable hydroxy alkyl aryl ketones include, but are not limited to, those of the formula:

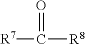

where R⁷ is a linear, branched, or cyclic C₂-C₂₀ alkyl group containing at least one hydroxyl group and R⁸ is a C₆-C₂₀ aryl, alkaryl, or aralkyl group. In an embodiment, the hydroxy alkyl aryl ketone is 1-hydroxy cycohexyl phenyl ketone.

Another illustrative embodiment of ACA 10 includes binder 42 formed from the reaction product of between 8% and 12% by weight of the compound described above, between 71% and 79% of a phenolic resin, no more than about 6% by weight of a catalyst, such as a quaternary cyanyl R-substituted amine, and no more than about 12% by weight of the UV modifier system. Any suitable phenolic resin may be used. Suitable phenolic resins include, but are not limited to, novalac resins and revol resins. In an embodiment of the invention, the phenolic resin is a novalac resin formed as the reaction product of formaldehyde and one or more of phenol, cresol, bisphenol-A and bisphenol-F. The quaternary cyanyl R-substituted amine may be as described above. This binder 42 may be mixed with about 14% by weight of particles 40 to form ACA 10. In this embodiment, particles 40 are solid nickel spheres coated with gold.

Another illustrative embodiment of ACA 10 includes binder 42 formed from the reaction product of between 71% and 79% by weight of phenolic resin, as described above, 8% to 12% by weight of a thermally polymerized aromatic epoxy resin and no more than about 6% by weight of a catalyst, such as quaternary cyanyl R-substituted amine as described above. The particles 40 added to this binder 42 to form ACA 10 include about 10% by weight of solid carbon/graphite spheres having a coating of gold over a coating of nickel and about 4% by weight of solid glass spheres having a coating of gold over a coating of nickel.

Another illustrative embodiment of ACA 10 includes binder 42 formed from the reaction product of between 71% and 79% by weight of a phenolic resin, as described above, 8% to 12% by weight of a phenoxy modified epoxy novalac resin and no more than about 6% by weight of a catalyst, such as quaternary cyanyl R-substituted amine as described above. The particles 40 added to this binder 42 to form ACA 10 include about 10% by weight of solid carbon/graphite spheres having a coating of gold over a coating of nickel and about 4% by weight of solid glass spheres having a coating of gold over a coating of nickel.

The foregoing embodiments of ACA 10 have a viscosity between 30,000 centi-poise and 45,000 centi-poise at 25° C. and a viscosity of less than 50 centi-poise between 75° C. and 150° C. This change in viscosity in combination with the exposure of ACA 10 to a suitable curing temperature in the presence of magnetic field 34 enables the particles 40 suspended in binder 42 to align under the influence of magnetic field 34 to form adjacent, but electrically isolated, parallel conductive paths between adjacent pairs of aligned contacts having an edge-to-edge spacing as close as 20-25 μm. The isolation of these adjacent parallel isolating conductive paths was confirmed by electrical measurement thereof.

Particles 40 formed from solid mica particles or flakes and/or hollow glass spheres having a coating of noble metal, such as gold or silver, over a coating of nickel may reduce the edge-to-edge spacing of the parallel conductive paths (as compared to the edge-to-edge spacing realized utilizing similarly sized solid nickel spheres coated with a coating of noble metal, solid carbon/graphite spheres having a coating of noble metal over a coating of nickel, and/or solid glass spheres having a coating of noble metal over a coating of nickel). It is believed that the lower weight of the particles 40 formed from solid mica particles or flakes and/or the hollow glass spheres enables them to move more readily under the influence of magnetic field 34 before binder 42 hardens sufficiently to prevent their movement. Furthermore, smaller sizes of particles 40 enable isolated, parallel conductive paths to be formed between adjacent pairs of aligned contacts having a closer edge-to-edge spacing than larger-size particles 40.

As mentioned above, in some embodiments, particles 40 of ACA 10 may be dispersed in a UV-curable binder 42. In one illustrative embodiment, UV-curable binder 42 may comprise a polymer mix of vinyl acrylate and epoxy acrylate. In some embodiments, binder 42 may comprise up to 1% by weight of one or more dispersants, such as by way of example, stearic acid, to reduce any clumping of particles 40 in ACA 10. Furthermore, in some embodiments, binder 42 may comprise up to 1% by weight of one or more tackifiers. ACA 10 may comprise, by way of example, about 8% to about 30% by weight of particles 40 dispersed in UV-curable binder 42. The viscosity of ACA 10 may be adjusted by adding variable amounts of solvent, based on the dispensing method to be used to deposit ACA 10 on substrate 6. Illustrative dispensing methods for ACA 10 include screen printing and stenciling.

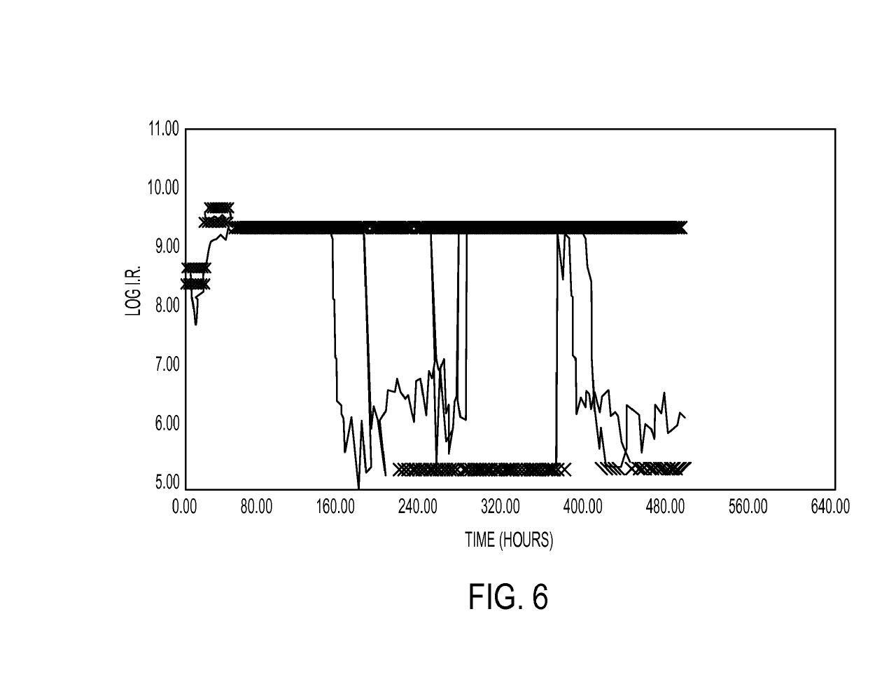

Over time, particularly in the presence of moisture, the electrically conductive material coating each of particles 40 may begin to migrate through binder 42 of cured ACA 10. This migration of the electrically conductive material of particles 40 may have the adverse effects of breaking electrical contact between aligned contacts 4, 8 of package 2 and substrate 6 and/or of shorting unaligned contacts 4, 8 of package 2 and substrate 6 (i.e., the migration of the electrically conductive material over time may cause the parallel conductive paths to no longer be electrically isolated from one another). By way of example, FIG. 6 illustrates a plot of insulation resistance (I.R.), at 50 V bias, for one illustrative embodiment of ACA 10 over approximately 500 hours, where the ACA 10 was subjected to 80° C. and 80% relative humidity. As can be seen from FIG. 6, the insulation resistance of ACA 10 drops over time; this is believed to be due primarily to migration of the electrically conductive material of particles 40 within ACA 10.

To reduce migration of the electrically conductive material of particles 40, illustrative embodiments of ACA 10 may additionally include a moisture barrier 41 applied to each particle 40. For instance, a chemical modifier (e.g., a mix of phenolic novolak in furfural solvent) may be applied to particles 40, before particles 40 are dispersed in binder 42. High-speed mixing may be used to coat each particle 40 with the chemical modifier to provide moisture barrier 41 outside the layer of electrically conductive material of each particle 40. In one illustrative embodiment, the chemical modifier used to provide moisture barrier 41 may be a mix of phenolic novolak in furfural solvent. It is contemplated that this chemical modifier may be 30-70% phenolic novolak by weight and 30-70% furfural solvent by weight. For instance, in one embodiment, the chemical modifier is a 50:50 mix of phenolic novolak and furfural solvent. In other embodiments, moisture barrier 41 may be formed of a carbon layer, which may increase resistance of particles 40 but has the advantage of better bio-compatibility.

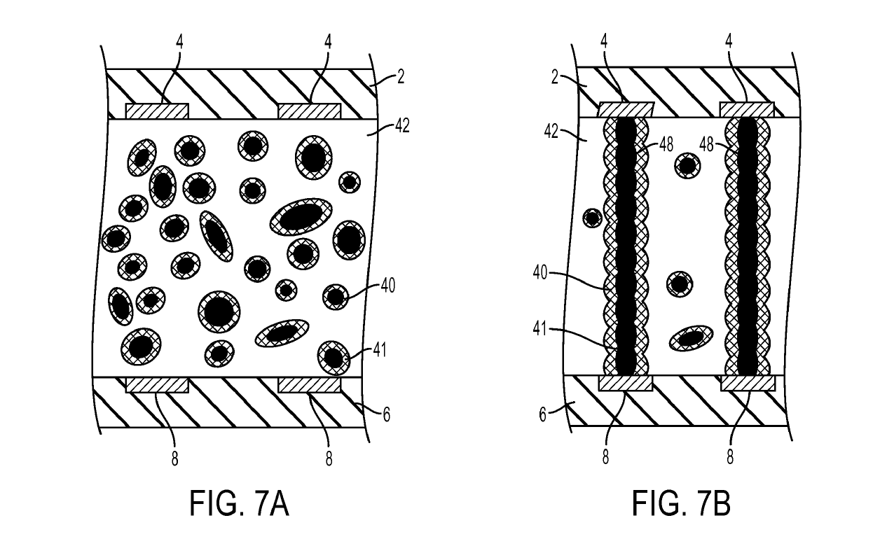

Referring now to FIG. 7A, one illustrative embodiment of ACA 10 including a moisture barrier 41 applied to each particle 40 is shown in diagrammatic cross-section. ACA 10 is disposed between package 2 and substrate 6 (including the aligned contacts 4, 8 thereof), as described above. Prior to ACA 10 being subjected to magnetic field 34, particles 40 are randomly distributed in binder 42. As shown in FIG. 7A, each particle 40 is individually surrounded by a moisture barrier 41. Upon application of magnetic field 34, particles 40 form parallel conductive paths 48 between pairs of aligned contacts 4, 8, as shown in FIG. 7B. As particles 40 align to form parallel conductive paths 48, moisture barrier 41 between adjacent particles 40 is displaced, such that the electrically conductive material of adjacent particles 40 comes into contact, allowing a conduction path to form between contact 4 and contact 8. However, moisture barrier 41 remains between each parallel conductive path 48 and binder 42, helping to reduce subsequent migration of the electrically conductive material of particles 40.

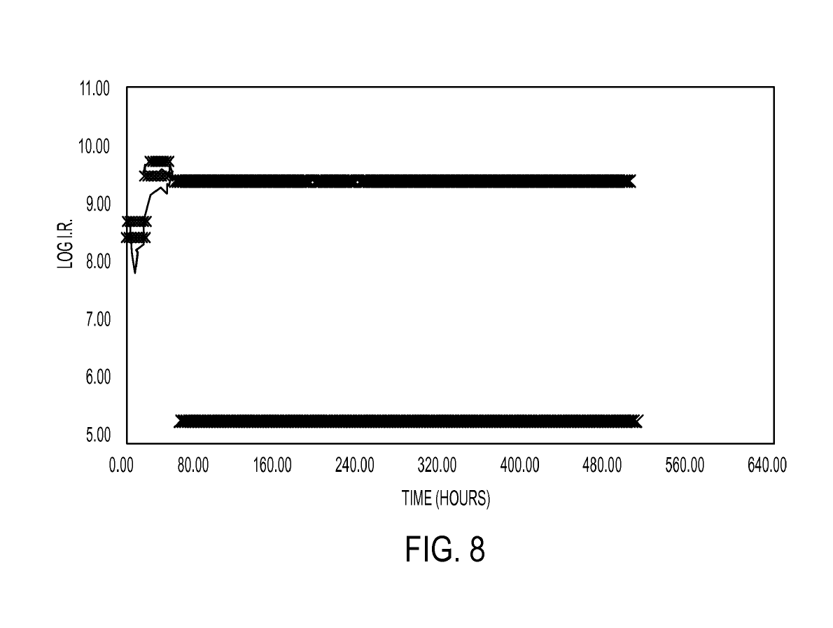

An illustrative embodiment of ACA 10 including moisture barrier 41 (specifically, a 50:50 mix of phenolic novolak and furfural solvent) applied to particles 40 was tested. FIG. 8 illustrates a plot of insulation resistance (I.R.), at 50 V bias, for this ACA 10 over approximately 500 hours, where the ACA 10 was subjected to 80° C. and 80% relative humidity. As can be seen from FIG. 8, the insulation resistance of ACA 10 remains relatively constant over time, indicating that moisture barrier 41 has reduced migration of the electrically conductive material of particles 40 within ACA 10. It is believe that the presently disclosed moisture barrier 41 may reduce migration of the electrically conductive material of particles 40 within ACA 10 for up to 1000 hours (or more) at low voltage conditions.

In some illustrative embodiments, any of the ACA 10 described above may be used to secure one or more radio-frequency identification (“RFID”) chips 2 to a substrate 6. The ACA 10 used in such embodiments may be heat-curable and/or UV-curable. The substrate 6 used in such embodiments may be a rigid board or a flexible film or sheet. Where the particular ACA 10 used is UV-curable, the substrate 6 may be partially or fully transparent to facilitate curing of the ACA 10. One or more antennas may be printed on the substrate 6 in electrical connection to one or more of the contacts 8 on the substrate. As such, when the RFID chip(s) 2 are coupled to substrate 6 (in electrical connection to the contacts 8) using the ACA 10, these printed antenna(s) may function as antennas for the RFID chip(s) 2. In one illustrative embodiment, the antenna(s) may be formed using silver ink printed on the substrate 6. In this embodiment, the ACA 10 may be UV-curable (to avoid heat damage to the silver ink). In another illustrative embodiment, the antenna(s) may be formed using aluminum traces printed on a paper substrate 6. In this embodiment, the ACA 10 may be heat-curable (due to the higher melting point of aluminum).

In other illustrative embodiments, any of the ACA 10 described above may be used to secure one or more light-emitting diodes (“LEDs”) 2 to a substrate 6. The LEDs 2 may be either packaged or unpackaged. The ACA 10 used in such embodiments may be heat-curable and/or UV-curable. The substrate 6 used in such embodiments may be a rigid board or a flexible film or sheet. Where the particular ACA 10 used is UV-curable, the substrate 6 may be partially or fully transparent to facilitate curing of the ACA 10. Where multiple LEDs 2 are secured to the same substrate 6 using ACA 10, the LEDs 2 may be of uniform or differing size(s).

In still other illustrative embodiments, any of the ACA 10 described above may be used to secure one or more chip-on-board (“COB”) light-emitting diodes (“LEDs”) 2 to a substrate 6. COB LEDs (as compared to “through hole” or “surface mounted” LEDs) may provide greater light output (lumens) in a smaller package size and also create a more consistent light beam. The ACA 10 used in such embodiments may be heat-curable and/or UV-curable. The substrate 6 used in such embodiments may be a rigid board or a flexible film or sheet. Where the particular ACA 10 used is UV-curable, the substrate 6 may be partially or fully transparent to facilitate curing of the ACA 10. In one illustrative embodiment, one or more COB LEDs 2 may be secured to a rigid substrate 6 using a heat-curable ACA 10 (including nickel particles 40 with an electrically conductive coating comprising 40-50% silver) that is cured under a magnetic field of 200-2000 Gauss.

While certain illustrative embodiments have been described in detail in the drawings and the foregoing description, such an illustration and description is to be considered as exemplary and not restrictive in character, it being understood that only illustrative embodiments have been shown and described and that all changes and modifications that come within the spirit of the disclosure are desired to be protected. There are a plurality of advantages of the present disclosure arising from the various features of the apparatus, systems, and methods described herein. It will be noted that alternative embodiments of the apparatus, systems, and methods of the present disclosure may not include all of the features described yet still benefit from at least some of the advantages of such features. Those of ordinary skill in the art may readily devise their own implementations of the apparatus, systems, and methods that incorporate one or more of the features of the present invention and fall within the spirit and scope of the present disclosure.

1. Apparatus comprising:
a substrate comprising one or more electrical contacts; and
one or more integrated circuits secured to the substrate by an anisotropic conductive adhesive (ACA);
wherein the ACA comprises a plurality of particles suspended in a curable binder, the plurality of particles forming electrically conductive and isolated parallel paths between the one or more electrical contacts and the one or more integrated circuits as a result of the ACA being subjected to a magnetic field before or during curing of the binder.

2. The apparatus of claim 1, wherein the one or more integrated circuits comprise one or more light-emitting diodes.

3. The apparatus of claim 1, wherein the one or more integrated circuits comprise one or more chip-on-board light-emitting diodes.

4. The apparatus of claim 1, wherein the one or more integrated circuits comprise one or more radio-frequency identification chips.

5. The apparatus of claim 1, wherein the one or more integrated circuits comprise one or more packaged integrated circuits.

6. The apparatus of claim 1, wherein the one or more integrated circuits comprise one or more unpackaged integrated circuits.

7. The apparatus of claim 1, wherein the substrate comprises a rigid substrate.

8. The apparatus of claim 1, wherein the substrate comprises a flexible substrate.

9. The apparatus of claim 1, wherein the substrate comprises a transparent substrate.

10. The apparatus of claim 1, wherein the substrate comprises plastic.

11. The apparatus of claim 1, wherein the substrate comprises glass.

12. The apparatus of claim 1, wherein the substrate comprises a paper.

13. The apparatus of claim 1, wherein the substrate comprises polyester.

14. The apparatus of claim 1, wherein the substrate comprises polyvinyl chloride.

15. The apparatus of claim 1, wherein the substrate comprises polycarbonate.

16. The apparatus of claim 1, wherein the substrate comprises polystyrene.

17. The apparatus of claim 1, wherein the one or more electrical contacts comprise silver.

18. The apparatus of claim 1, wherein the one or more electrical contacts comprise aluminum.

19. The apparatus of claim 1, wherein the one or more electrical contacts are transparent.

20. The apparatus of claim 1, wherein the substrate further comprises an antenna connected to at least one of the electrical contacts.
